(19) United States
(12) Patent Application Publication
(10) Pub. No.: US 2025/0380402 A1
(43) Pub. Date: Dec. 11, 2025

(54) SEMICONDUCTOR MEMORY DEVICE

(71) Applicant: Samsung Electronics Co., Ltd., Suwon-si (KR)

(72) Inventors: Sung Joon Park, Suwon-si (KR); Masayuki Terai, Suwon-si (KR)

(21) Appl. No.: 19/019,816

(22) Filed: Jan. 14, 2025

(30) Foreign Application Priority Data
Jun. 7, 2024 (KR) 10-2024-0074461

(51) Int. Cl. H10B 12/00

(52) U.S. Cl. CPC H10B 12/33; H10B 12/05; H10B 12/50

(57) ABSTRACT

A semiconductor memory device includes a data storage pattern on a substrate, a buried contact on the data storage pattern, a bit-line spaced apart from the buried contact in a first direction perpendicular to an upper surface of the substrate and extending in a second direction parallel to the upper surface of the substrate, a channel pattern between the buried contact and the bit-line and connected to the buried contact and the bit-line, and a word-line on the channel pattern and extending in a third direction parallel to the upper surface of the substrate and intersecting the second direction. The channel pattern includes a first surface contacting the buried contact and a second surface contacting the bit-line. A width in the second direction of the first surface of the channel pattern is greater than a width in the second direction of the second surface of the channel pattern.

### CROSS-REFERENCE TO RELATED APPLICATION

This application claims priority from Korean Patent Application No. 10-2024-0074461 filed on Jun. 7, 2024 in the Korean Intellectual Property Office, and all the benefits accruing therefrom under 35 U.S.C. § 119, the contents of which in its entirety are herein incorporated by reference.

### BACKGROUND

The present disclosure relates generally to a semiconductor memory device, and more specifically, to a semiconductor memory device including a vertical channel transistor (VCT).

In order to meet high performance and low price of a semiconductor memory device as demanded by consumers, it is required to increase integration of the semiconductor memory device. The integration of the semiconductor memory device is an important factor in determining a price thereof. Thus, the semiconductor memory device particularly having increased integration is required.

Integration of a two-dimensional (2D) or planar semiconductor memory device is largely determined based on an occupancy area of a unit memory cell, and therefore is greatly affected by a level of a fine pattern formation skill. However, ultra-expensive equipment is required for formation of fine patterns. Thus, although the integration of the 2D semiconductor memory device is increasing, the increase thereof is limited. Accordingly, a semiconductor memory device including a vertical channel transistor in which a channel extends in a vertical direction is being proposed.

### SUMMARY

A technical purpose to be achieved by the present disclosure is to provide a semiconductor memory device with improved integration and electrical characteristics.

Purposes according to the present disclosure are not limited to the above-mentioned purpose. Other purposes and advantages according to the present disclosure that are not mentioned may be understood based on the following descriptions, and may be more clearly understood based on embodiments according to the present disclosure. Further, it will be easily understood that the purposes and advantages according to the present disclosure may be realized using means illustrated in the claims and combinations thereof.

According to an aspect of the present disclosure, there is provided a semiconductor memory device comprising a data storage pattern on a substrate, a buried contact on the data storage pattern, a bit-line spaced apart from the buried contact in a first direction and extending in a second direction, a channel pattern between the buried contact and the bit-line and connected to the buried contact and the bit-line, and a word-line on the channel pattern and extending in a third direction, wherein the channel pattern includes a first surface contacting the buried contact and a second surface contacting the bit-line, wherein a width in the second direction of the first surface of the channel pattern is greater than a width in the second direction of the second surface of the channel pattern.

According to an aspect of the present disclosure, there is provided a semiconductor memory device comprising a data storage pattern on a substrate, a buried contact on the data storage pattern, a channel pattern on an upper surface of the buried contact and connected to the buried contact, a bit-line on the channel pattern, connected to the channel pattern, and extending in a first direction, and a word-line on the channel pattern and between the buried contact and the bit-line, wherein the word-line extends in a second direction, wherein the channel pattern includes a horizontal portion and a vertical portion connected to the horizontal portion, wherein the horizontal portion of the channel pattern extends in the first direction and along the upper surface of the buried contact, wherein the vertical portion of the channel pattern protrudes in a third direction from the horizontal portion of the channel pattern.

According to an aspect of the present disclosure, there is provided a semiconductor memory device comprising: a peripheral circuit element on a substrate, a data storage pattern on the peripheral circuit element, a buried contact on the data storage pattern, a bit-line spaced apart from the buried contact in a first direction and extending in a second direction, a channel pattern between the buried contact and the bit-line and contacting the buried contact and the bit-line, and a word-line on the channel pattern and extending in a third direction, wherein the channel pattern includes a first surface contacting the buried contact and a second surface contacting the bit-line, wherein a width in the second direction of the first surface of the channel pattern is greater than a width in the second direction of the second surface of the channel pattern.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail embodiments thereof with reference to the attached drawings, wherein like reference numerals (when used) indicate corresponding elements throughout the several views, and in which:

FIG. 1 is a schematic layout diagram for illustrating a semiconductor memory device according to some embodiments;

FIG. 2 is a schematic cross-sectional view taken along line A-A in FIG. 1;

FIG. 3 is a schematic cross-sectional view taken along line A-A in FIG. 1 according to some further embodiments of the present disclosure;

FIG. 4 is an enlarged view of a region M of FIG. 2 and FIG. 3 according to some embodiments;

FIG. 5 is an enlarged view of the region M of FIG. 2 and FIG. 3 according to some further embodiments;

FIG. 6 is an enlarged view of the region M of FIG. 2 and FIG. 3 according to some further embodiments; and

FIGS. 7 to 22 are schematic diagrams depicting intermediate processes in an example semiconductor memory device manufacturing method according to some embodiments.

### DETAILED DESCRIPTION

Although terms such as, but not limited to, first, second, upper, and lower may be used herein to describe various elements or components, these elements or components are not intended to be limited by such terms. Rather, the terms are merely used herein to distinguish one element or component from another element or component, or to describe a position or orientation of an element or component relative to another element or component. Therefore, a first element or component as mentioned below may also be a second element or component within the technical spirit of the present disclosure. Further, a lower element or component as mentioned below may also be an upper element or component within the technical spirit of the present disclosure depending on an orientation of the element or component. A semiconductor memory device according to embodiments of the present disclosure may include memory cells, each including a vertical channel transistor (VCT).

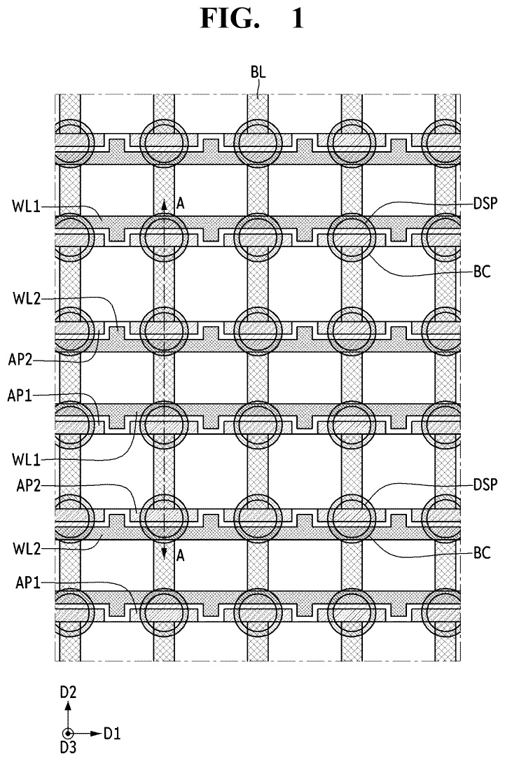

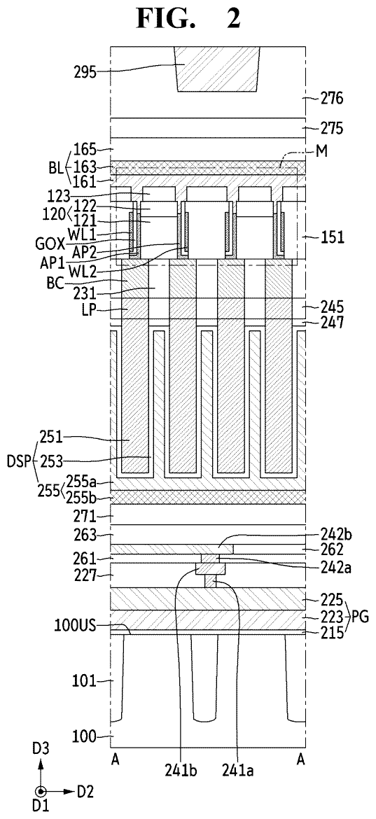

FIG. 1 is a schematic layout diagram for illustrating a semiconductor memory device according to some embodiments. FIG. 2 is a schematic cross-sectional view taken along line A-A in FIG. 1.

Referring to FIG. 1 and FIG. 2, a semiconductor memory device according to some embodiments may include a substrate 100, a bit-line BL, a word-line WL1 and WL2, a channel pattern AP1 and AP2, a data storage pattern DSP, a peripheral connection structure (which may include a first peripheral connection via 242a and a first peripheral connection wiring 242b), and a connection pad 295.

The substrate 100 may be a silicon substrate, or may include a material other than silicon, such as silicon germanium, indium antimonide, lead telluride compound, indium arsenide, indium phosphide, gallium arsenide, or gallium antimonide. However, embodiments of the present disclosure are not limited thereto.

The substrate 100 may include an upper surface 100US. An element isolation film 101 may be disposed within the substrate 100. The element isolation film 101 may define an active area within the substrate 100. The element isolation film 101 may include an insulating material.

Although not explicitly shown, the substrate 100 may include a cell array area where the data storage pattern DSP is disposed, and a peripheral circuit area defined around (i.e., surrounding or extending around) the cell array area. A cell area element isolation film may be disposed on the peripheral circuit area of the substrate 100. In a plan view, the cell area element isolation film may define a cell array area of the substrate 100.

A peripheral gate structure PG may be disposed on the substrate 100. For example, the peripheral gate structure PG may be disposed on the upper surface 100US of the substrate. The peripheral gate structure PG may extend across the cell array area and the peripheral circuit area. In other words, a portion of the peripheral gate structure PG may be disposed in the cell array area of the substrate 100, and the remainder of the peripheral gate structure PG may be disposed in the peripheral circuit area of the substrate 100.

The peripheral gate structure PG may be included in each of a sensing transistor, a transfer transistor, and a driving transistor. For example, the peripheral gate structure PG included in the sensing transistor may be disposed on the substrate 100 of the cell array arca. However, embodiments of the present disclosure are not limited thereto. In another example, a type of a transistor of the peripheral circuit disposed on the substrate 100 of the cell array arca may vary depending on a design and an arrangement of the semiconductor memory device.

The peripheral gate structure PG may include a peripheral gate insulating film 215, a peripheral lower conductive pattern 223, and a peripheral upper conductive pattern 225. The peripheral gate insulating film 215 may include a silicon oxide film, a silicon oxynitride film, a high dielectric constant insulating film having a higher dielectric constant than that of the silicon oxide film, or a combination thereof. The high dielectric constant insulating film may include, but is not limited to, at least one of, for example, metal oxide, metal oxynitride, metal silicon oxide, or metal silicon oxynitride.

Each of the peripheral lower conductive pattern 223 and the peripheral upper conductive pattern 225 may include a conductive material. For example, each of the peripheral lower conductive pattern 223 and the peripheral upper conductive pattern 225 may include at least one of a semiconductor material doped with impurities, a conductive silicide compound, a conductive metal nitride, a two-dimensional (2D) material, a metal, or a metal alloy. In a semiconductor memory device according to some embodiments, the two-dimensional material may be a metallic material and/or a semiconductor material. The two-dimensional material (2D material) may include a two-dimensional allotrope or a two-dimensional compound. For example, the 2D material may include at least one of graphene, molybdenum disulfide (MoS₂), molybdenum diselenide (MoSe₂), tungsten diselenide (WSe₂), and tungsten disulfide (WS₂). However, the present disclosure is not limited thereto. In other words, the above-described two-dimensional materials are listed only by way of example. The two-dimensional material that may be included in the semiconductor memory device of the present disclosure is not limited to the above-described materials. The peripheral gate structure PG is shown as including a plurality of conductive patterns. However, embodiments of the present disclosure are not limited thereto.

A first peripheral lower insulating film 227 is disposed on the upper surface 100US of the substrate. The first peripheral lower insulating film 227 may include an insulating material. A peripheral wiring line 241a and a peripheral contact plug 241b may be disposed within the first peripheral lower insulating film 227. The peripheral wiring line 241a and the peripheral contact plug 241b may be connected to a conductive pattern (e.g., 223 and/or 225) of the peripheral gate structure PG. Although not explicitly shown, the peripheral wiring line 241a and the peripheral contact plug 241b may be connected to a source/drain area disposed on at least one side of the peripheral gate structure PG.

Although it is shown that the peripheral wiring line 241a and the peripheral contact plug 241b are embodied as different films, the present disclosure is not limited thereto. A boundary between the peripheral wiring line 241a and the peripheral contact plug 241b may not be defined. Each of the peripheral wiring line 241a and the peripheral contact plug 241b may include a conductive material.

A third peripheral lower insulating film 261 and a second peripheral lower insulating film 262 may be disposed on the peripheral wiring line 241a and the peripheral contact plug 241b. Each of the third peripheral lower insulating film 261 and the second peripheral lower insulating film 262 may include an insulating material. In another example, unlike what is shown, an insulating film as a single film may be disposed on the peripheral wiring line 241a and the peripheral contact plug 241b.

The peripheral connection structure 242a and 242b may be connected to the peripheral wiring line 241a. Each of the first peripheral connection via 242a and the first peripheral connection wiring 242b of the peripheral connection structure may include a conductive material. A fourth peripheral lower insulating film 263 may be disposed on the peripheral connection structure 242a and 242b. The fourth peripheral lower insulating film 263 may include an insulating material.

The data storage patterns DSP may be disposed on the fourth peripheral lower insulating film 263. The fourth peripheral lower insulating film 263 may be disposed between the data storage pattern DSP and the peripheral connection structure 242a.

The data storage patterns DSP may be electrically connected to the first and second channel patterns AP1 and AP2, respectively. The data storage patterns DSP may be arranged in a matrix form along a first direction D1 and a second direction D2.

In this regard, the first direction D1 and the second direction D2 may be perpendicular to a third direction D3. The first direction D1 may intersect the second direction D2. For example, the third direction D3 may be a thickness (i.e., vertical) direction of the substrate 100. The first direction D1 and the second direction D2 may be parallel to the upper surface 100US of the substrate 100 and the third direction D3 may be perpendicular to the upper surface 100US of the substrate 100.

In an example, each of the data storage patterns DSP may be a capacitor. Each of the data storage patterns DSP may include each of storage electrodes 251, a plate electrode 255, and a capacitor dielectric film 253 interposed between each of the storage electrodes 251 and the plate electrode 255. In a plan view, the storage electrode 251 may have various shapes, such as circular, oval, rectangular, square, diamond, or hexagonal shapes, although embodiments are not limited thereto. The storage electrodes 251 may extend, in the third direction D3, through an upper etch stop film 247. The upper etch stop film 247 may include an insulating material.

The plate electrode 255 may include a lower plate electrode 255b and an upper plate electrode 255a. Unlike what is shown, the plate electrode 255 may be a single film. Each of the storage electrode 251 and the plate electrode 255 may include at least one of, for example, a doped semiconductor material, conductive metal nitride, conductive metal silicon nitride, metal carbonitride, conductive metal silicide, conductive metal oxide, or metal.

The capacitor dielectric film 253 may include at least one of a ferroelectric material, an antiferroelectric material, or a paraelectric material. For example, the capacitor dielectric film 253 may include one of a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, and a combination of a ferroelectric material, an antiferroelectric material, and a paraelectric material.

Alternatively, each of the data storage patterns DSP may be embodied as a variable resistance pattern that may be switched between two resistance states under an electrical pulse applied to a memory element. For example, each of the data storage patterns DSP may include a phase-change material having a crystal state that varies depending on an amount of current, perovskite compounds, transition metal oxides, magnetic materials, ferromagnetic materials, or antiferromagnetic materials.

A peripheral upper insulating film 271 may be disposed on the fourth peripheral lower insulating film 263. The upper etch stop film 247 may be disposed on the peripheral upper insulating film 271. The data storage patterns DSP may be disposed on the peripheral upper insulating film 271. Although not shown, the peripheral upper insulating film 271 may cover a side wall of the plate electrode 255. The term “cover” (or “covers,” or like terms), as may be used herein, is intended to broadly refer to an element, structure or layer that is on or over another element, structure or layer, either directly or with one or more other intervening elements, structures or layers therebetween. The peripheral upper insulating film 271 may include an insulating material.

Each of a plurality of landing pads LP may be disposed on each of the data storage patterns DSP. Each of the landing pads LP may be disposed on each of the storage electrodes 251. The storage electrode 251 may be in contact with the landing pad LP. The term “contact” (or “contacting,” or like terms, such as “connect” or “connecting”), as may be used herein, is intended to refer to a physical and/or electrical connection between two or more elements, and may include other intervening elements. As used herein, the term “and/or” includes any and all combinations of one or more of the associated listed items.

Each of pad isolation insulation patterns 245 may be disposed between adjacent ones of the landing pads LP. In a plan view, the landing pads LP may be arranged in a matrix form along the first direction D1 and the second direction D2. The pad isolation insulation pattern 245 may include an insulating material.

Each of the data storage patterns DSP may entirely overlap or partially overlap each of the landing pads LP in the third direction D3. The term “overlap” (or “overlapping,” or like terms), as may be used herein, is intended to broadly refer to a first element that intersects with at least a portion of a second element in the vertical direction (i.e., third direction D3), but does not require that the first and second elements be completely aligned with one another in a horizontal plane (i.e., first direction D1 and/or second direction D2). Each of the data storage patterns DSP may contact an entirety or a portion of an upper surface of each of the landing pads LP.

The landing pad LP may include a conductive material. For example, the landing pad LP may include at least one of doped polysilicon, conductive metal nitride, conductive metal silicon nitride, metal carbonitride, conductive metal silicide, conductive metal oxide, two-dimensional (2D) material, or metal.

Each of buried contacts BC may be disposed on each of the landing pads LP. The buried contacts BC may be electrically connected to the first and second channel patterns AP1 and AP2, respectively. Each buried contact BC may have various shapes, such as circular, oval, rectangular, square, diamond, or hexagonal shape in a plan view.

The buried contact BC may include a conductive material. The buried contact BC may include at least one of, for example, doped polysilicon, conductive metal nitride, conductive metal silicon nitride, metal carbonitride, conductive metal silicide, conductive metal oxide, two-dimensional material, or metal. Each of the buried contacts BC may extend through a contact interlayer insulating film 231. The contact interlayer insulating film 231 may be disposed on the pad isolation insulating pattern 245. The contact interlayer insulating film 231 may include an insulating material.

The first channel patterns AP1 and the second channel patterns AP2 may be arranged on the data storage patterns DSP. The data storage patterns DSP may be disposed between the first channel patterns AP1 and the substrate 100. The data storage patterns DSP may be disposed between the second channel patterns AP2 and the substrate 100. The first channel patterns AP1 and the second channel patterns AP2 may be arranged alternately with each other along the second direction D2.

The first channel patterns AP1 may be spaced apart from each other in the first direction D1. The first channel patterns AP1 may be spaced apart from each other by an equal spacing. The second channel patterns AP2 may be spaced apart from each other in the first direction D1. The second channel patterns AP2 may be spaced apart from each other by an equal spacing. The first channel pattern AP1 may be spaced apart from the second channel pattern AP2 in the second direction D2. The first and second channel patterns AP1 and AP2 may be two-dimensionally arranged along the first direction D1 and the second direction D2.

A mold insulating film 120 may be disposed between the first and second channel patterns AP1 and AP2. The mold insulating film 120 may include a first mold insulating film 121 and a second mold insulating film 122 sequentially stacked in the third direction D3. For example, the first mold insulating film 121 may include silicon oxide, and the second mold insulating film 122 may include silicon nitride. Unlike what is shown, the mold insulating film 120 may be embodied as a single film.

The first and second channel patterns AP1 and AP2 may have a symmetrical structure with respect to each other around the mold insulating film 120. Each of the first and second channel patterns AP1 and AP2 may include one of, for example, indium gallium zinc oxide (IGZO), indium zinc oxide (IZO) doped with impurities, indium oxide (InO), zinc oxide (ZnO), gallium oxide (GaO), tin oxide (SnO), aluminum zinc oxide (AZO), and indium tin oxide (ITO). In indium zinc oxide (IZO) doped with the impurities, the doped impurity may include at least one of, for example, magnesium (Mg), strontium (Sr), barium (Ba), scandium (Sc), yttrium (Y), lanthanum (La), titanium (Ti), zirconium (Zr), hafnium (Hf), aluminum (Al), tin (Sn), and tantalum (Ta).

The first and second word-lines WL1 and WL2 may be respectively disposed on the data storage patterns DSP. The first and second word-lines WL1 and WL2 may be respectively disposed on the buried contacts BC. The data storage patterns DSP may be disposed between the first word-lines WL1 and the substrate 100. The data storage patterns DSP may be disposed between the second word-lines WL2 and the substrate 100.

Each of the first and second word-lines WL1 and WL2 may extend in the first direction D1. The first and second word-lines WL1 and WL2 may be arranged alternately with each other in the second direction D2. The first and second word-lines WL1 and WL2 may be arranged to be spaced apart from each other in the second direction D2. Specifically, a word-line space filling film 151 may be disposed between the first and second word-lines WL1 and WL2. The word-line space filling film 151 may include an insulating material.

The first and second word-lines WL1 and WL2 may be spaced apart from the bit-lines BL and the buried contacts BC in the third direction D3. The first and second word-lines WL1 and WL2 may be located between the bit-lines BL and the buried contacts BC in the third direction D3.

Gate insulating patterns GOX may be respectively disposed between the first word-line WL1 and the first channel pattern AP1 and between the second word-line WL2 and the second channel pattern AP2. The gate insulation pattern GOX may extend in the first direction D1 in parallel with the first and second word-lines WL1 and WL2.

The gate insulating pattern GOX may include a silicon oxide film, a silicon oxynitride film, a high dielectric constant insulating film with a higher dielectric constant than that of the silicon oxide film, or a combination thereof.

The bit-lines BL may be disposed on top of the first and second channel patterns AP1 and AP2. The bit-lines BL may be disposed on top of the first word-line WL1 and the second word-line WL2. The bit-lines BL may be disposed on top of the first mold insulating film 121, the second mold insulating film 122, and a bit-line isolation film 123. The bit-lines BL may be disposed on top of the bit-line isolation film 123.

The bit-line BL may include a semiconductor pattern 161, a metal pattern 163, and a bit-line mask pattern 165 that are sequentially stacked in the third direction D3. Unlike what is shown, the bit-line BL may include one of the semiconductor pattern 161 and the metal pattern 163.

The semiconductor pattern 161 may include a conductive semiconductor material. The semiconductor pattern 161 may include at least one of polysilicon, polysilicon germanium, polygermanium, amorphous silicon, amorphous silicon germanium, or amorphous germanium. The metal pattern 163 may include a conductive material including metal. For example, the metal pattern 163 may include at least one of conductive metal nitride, conductive metal silicon nitride, metal carbonitride, conductive metal silicide, conductive metal oxide, two-dimensional material, or metal. The bit-line mask pattern 165 may include an insulating material such as silicon nitride or silicon oxynitride.

A first peripheral upper insulating film 275 and a second peripheral upper insulating film 276 may be sequentially stacked on the bit-line mask pattern 165 in the third direction D3. Each of the first peripheral upper insulating film 275 and the second peripheral upper insulating film 276 may include an insulating material.

The connection pad 295 may be disposed within the second peripheral upper insulating film 276. The connection pad 295 may include a conductive material.

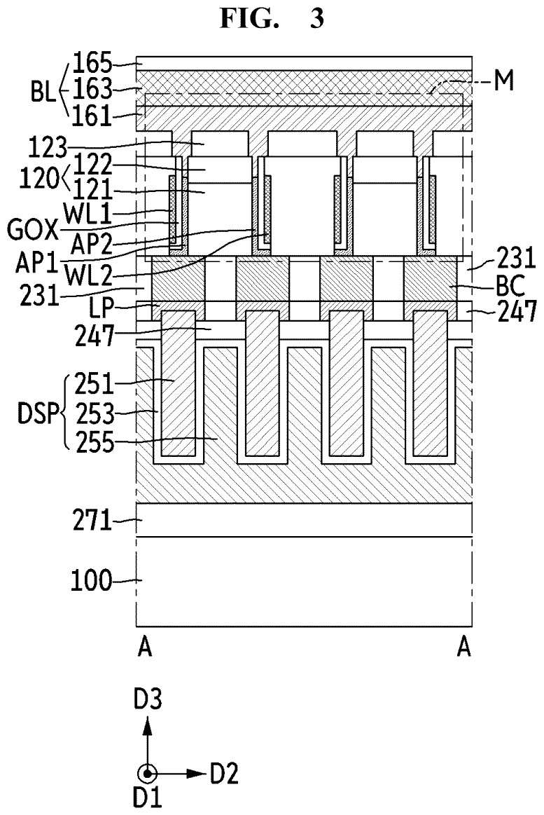

FIG. 3 is a schematic cross-sectional view taken along A-A in FIG. 1 according to some further embodiments of the present disclosure. For convenience of description, description about FIG. 3 is based on differences thereof from FIG. 2.

Referring to FIG. 1 and FIG. 3, a semiconductor memory device according to some further embodiments may include the substrate 100, the interlayer insulating film 271, the data storage pattern DSP, the word-line WL1 and WL2, the channel pattern AP1 and AP2 and the bit-line BL.

The interlayer insulating film 271 may be disposed on the substrate 100. The interlayer insulating film 271 may include an insulating material. The data storage pattern DSP may be disposed on the interlayer insulating film 271. In an example, the data storage pattern DSP may act as the capacitor. Each of the data storage patterns DSP may include each of the storage electrodes 251, the plate electrode 255, and the capacitor dielectric film 253 interposed between each of the storage electrodes 251 and the plate electrode 255. In a plan view, the storage electrodes 251 may have various shapes, such as circular, oval, rectangular, square, diamond, or hexagonal shapes. The storage electrodes 251 may extend through the upper etch stop film 247. The upper etch stop film 247 may include an insulating material.

The plate electrode 255 may be embodied as a single film. Unlike what is shown, the plate electrode 255 may include a lower plate electrode and an upper plate electrode.

The landing pads LP may be disposed on the data storage patterns DSP, respectively. Each landing pad LP may be disposed on each storage electrode 251. The storage electrode 251 may be in contact with the landing pad LP. The buried contacts BC may be disposed on the landing pads LP, respectively.

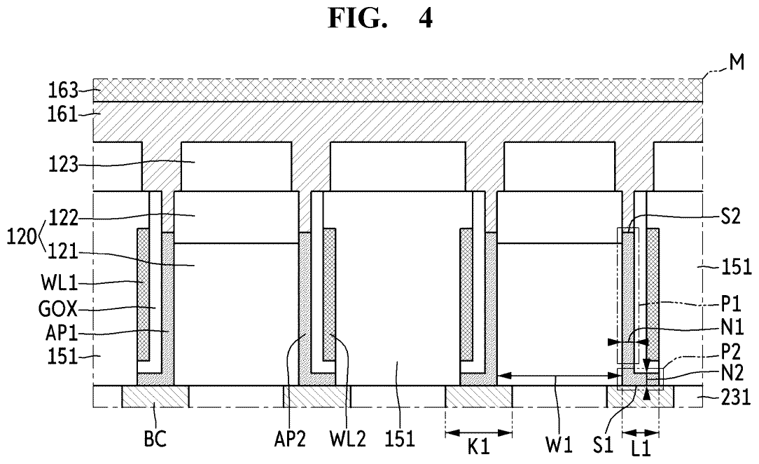

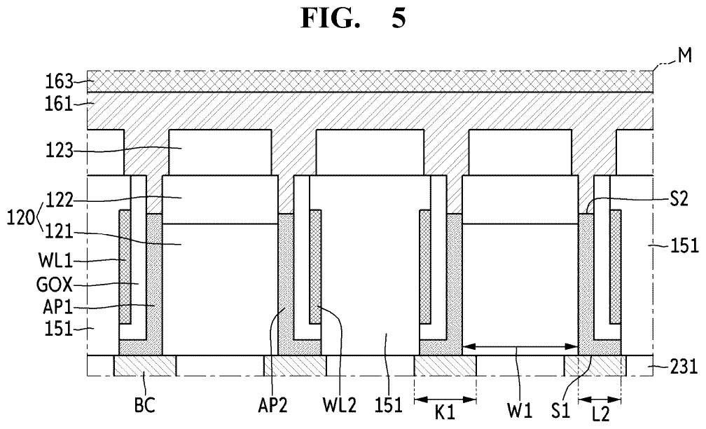

FIG. 4 is an enlarged view of a region M of FIG. 2 and FIG. 3 according to some embodiments. FIG. 5 is an enlarged view of the region M of FIG. 2 and FIG. 3 according to some further embodiments.

Referring to FIG. 4, the first and second channel patterns AP1 and AP2 may be disposed on the buried contacts BC, respectively. The first and second channel patterns AP1 and AP2 may be alternately arranged with each other and spaced apart from each other in the second direction D2.

The first and second channel patterns AP1 and AP2 may be disposed on the buried contacts BC, respectively. Specifically, each of the first and second channel patterns AP1 and AP2 may be disposed only on an upper surface of the buried contact BC. Each of the first and second channel patterns AP1 and AP2 may contact the upper surface of the buried contact BC. In other words, each of the first and second channel patterns AP1 and AP2 may not be disposed on the contact interlayer insulating film 231. Each of the first and second channel patterns AP1 and AP2 may not be in direct contact with the contact interlayer insulating film 231.

Each of the first and second channel patterns AP1 and AP2 may include a first portion P1 and a second portion P2 connected to each other. The first portion P1 may extend in the third direction D3, and the second portion P2 may extend in the second direction D2. The first portion P1 may protrude (i.e., extend) from the second portion P2 in the third direction D3. In other words, the second portion P2 may protrude from the first portion P1 in the second direction D2.

The first portion P1 may not directly contact the buried contact BC, and the second portion P2 may directly contact the buried contact BC. The first portion P1 may extend along a profile of a side wall of the mold insulating film 120, and the second portion P2 may extend along a profile of the upper surface of the buried contact BC and onto a side wall of the mold insulating film 120. A length L1 in the second direction D2 of the second portion P2 may be smaller than a length K1 in the second direction D2 of the buried contact BC. Specifically, a lower surface of the second portion P2 may be disposed only on the upper surface of the buried contact BC.

A thickness in the second direction D2 of the first portion P1 may be equal to a thickness in the third direction D3 of the second portion P2. In other words, the thickness of each of the first and second channel patterns AP1 and AP2 may be constant.

Each of the first and second channel patterns AP1 and AP2 may include a first surface S1 and a second surface S2 that are opposite to each other in the third direction D3. The first surface S1 may contact the buried contact BC, and the second surface S2 may contact the bit-line BL in FIG. 2 and FIG. 3 Specifically, the second surface S2 may contact the semiconductor pattern 161 of the bit-line BL.

The length L1 of the first surface S1 in the second direction D2 may be greater than a length N1 of the second surface S2 in the second direction D2. In other words, the lengths N1 and N2 in the second direction D2 of both opposing surfaces S1 and S2 of each of the first and second channel patterns AP1 and AP2, respectively, may be different from each other.

Referring to FIG. 5, a length L2 in the second direction D2 of the first surface S1 of each of the first and second channel patterns AP1 and AP2 may be different from the length (see L1 in FIG. 4) in the second direction D2 of the first surface S1 of each of the first and second channel patterns AP1 and AP2 as shown in FIG. 4. Specifically, the length L2 in the second direction D2 of the first surface S1 of each of the first and second channel patterns AP1 and AP2 in FIG. 5 may be greater than the length L1 in the second direction D2 of the first surface S1 of each of the first and second channel patterns AP1 and AP2 as shown in FIG. 4. In other words, the first surface S1 of each of the first and second channel patterns AP1 and AP2 in FIG. 5 may have a larger contact area with the buried contact BC compared to the semiconductor memory device in FIG. 4.

For reference, the length W1 of the mold insulating film 120 in the second direction D2 in FIG. 5 may be equal to the length W1 of the mold insulating film 120 in the second direction D2 as shown in FIG. 4. The length K1 of the buried contact BC in the second direction D2 in FIG. 5 may be equal to the length K1 of the buried contact BC in the second direction D2 as shown in FIG. 4.

As the length L2 in the second direction D2 of the first surface of each of the first and second channel patterns AP1 and AP2 increases, the contact resistance decreases, thereby improving the integration density and electrical characteristics of the semiconductor memory device.

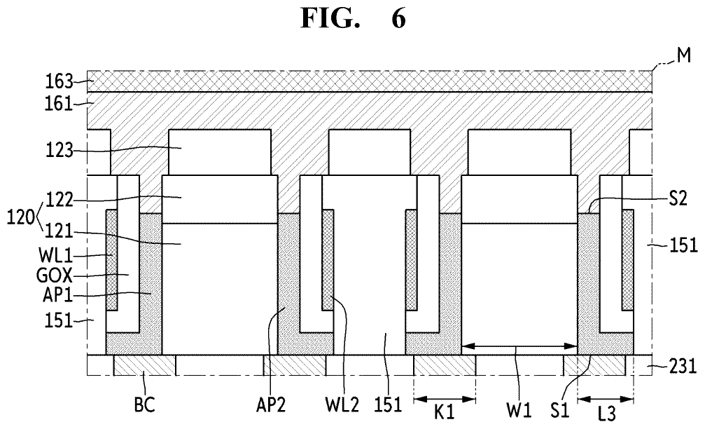

FIG. 6 is an enlarged view of the region M of FIG. 2 and FIG. 3 according to some further embodiments. For convenience of description, description about FIG. 6 is based on differences thereof from FIG. 4.

Referring to FIG. 6, a length L3 in the second direction D2 of the first surface S1 of each of the first and second channel patterns AP1 and AP2 may be different from the length (see L1 in FIG. 4) in the second direction D2 of the first surface S1 of each of the first and second channel patterns AP1 and AP2 as shown in FIG. 4. Specifically, the length L3 in the second direction D2 of the first surface S1 of each of the first and second channel patterns AP1 and AP2 in FIG. 6 may be greater than the length L1 in the second direction D2 of the first surface S1 of each of the first and second channel patterns AP1 and AP2 as shown in FIG. 4. In other words, the first surface S1 of each of the first and second channel patterns AP1 and AP2 in FIG. 6 may have a larger contact area with the buried contact BC compared to the semiconductor memory device in FIG. 4.

Each of the first and second channel patterns AP1 and AP2 may be disposed on the buried contact BC. Each of the first and second channel patterns AP1 and AP2 may be disposed on the upper surface of the buried contact BC and the upper surface of the contact interlayer insulating film 231. In other words, each of the first and second channel patterns AP1 and AP2 may be partially disposed on the contact interlayer insulating film 231. At least a portion of the first surface S1 of each of the first and second channel patterns AP1 and AP2 may be in direct contact with the contact interlayer insulating film 231.

For reference, the length W1 of the mold insulating film 120 in the second direction D2 in FIG. 6 may be equal to the length W1 of the mold insulating film 120 in the second direction D2 shown in FIG. 4. The length K1 of the buried contact BC in the second direction D2 in FIG. 6 may be equal to the length K1 of the buried contact BC in the second direction D2 as shown in FIG. 4.

As the length L3 in the second direction D2 of the first surface of each of the first and second channel patterns AP1 and AP2 increases, the contact resistance decreases, thereby improving the integration density and electrical characteristics of the semiconductor memory device.

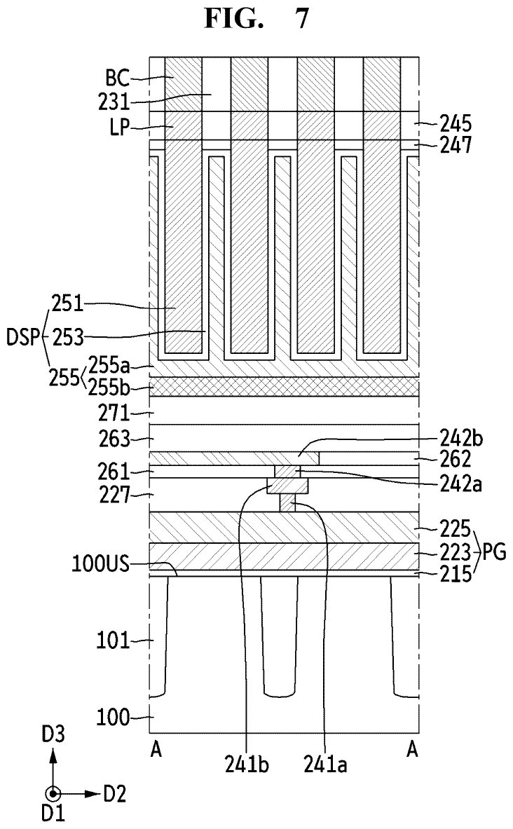

FIGS. 7 to 22 are schematic diagrams for illustrating intermediate processes in an example semiconductor memory device manufacturing method according to some embodiments.

Referring to FIG. 7, a substrate structure including the substrate 100, the peripheral lower insulating film 227, 261, 262, and 263, the data storage pattern DSP, the landing pad LP, and the buried contact BC may be provided.

For reference, the substrate structure may be a structure provided through a process of forming the buried contact BC and the data storage pattern DSP on a dummy substrate and then removing the dummy substrate.

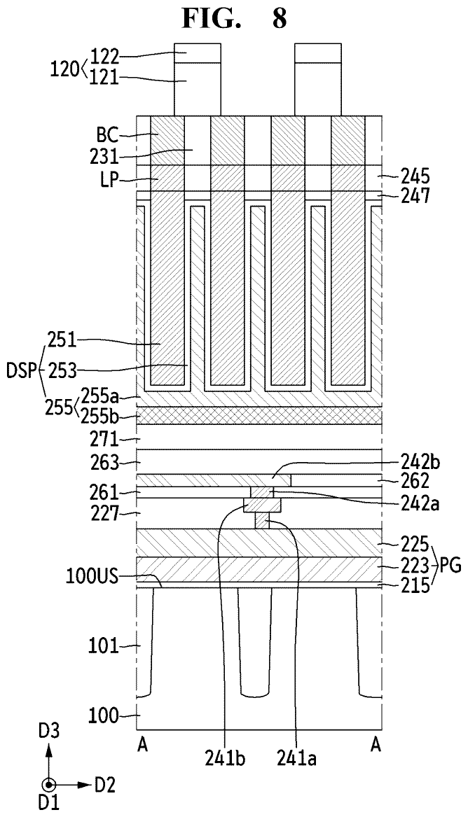

Referring to FIG. 8, the mold insulating film 120 may be formed.

Specifically, the first mold insulating film 121 may be formed on the buried contact BC, and the second mold insulating film 122 may be stacked on the first mold insulating film 121 in the third direction D3. For example, a first pre-mold insulating film and a second pre-mold insulating film may be formed on the buried contact BC and the data storage pattern DSP, and then, the first pre-mold insulating film and the second pre-mold insulating film may be patterned to form the mold insulating film 120.

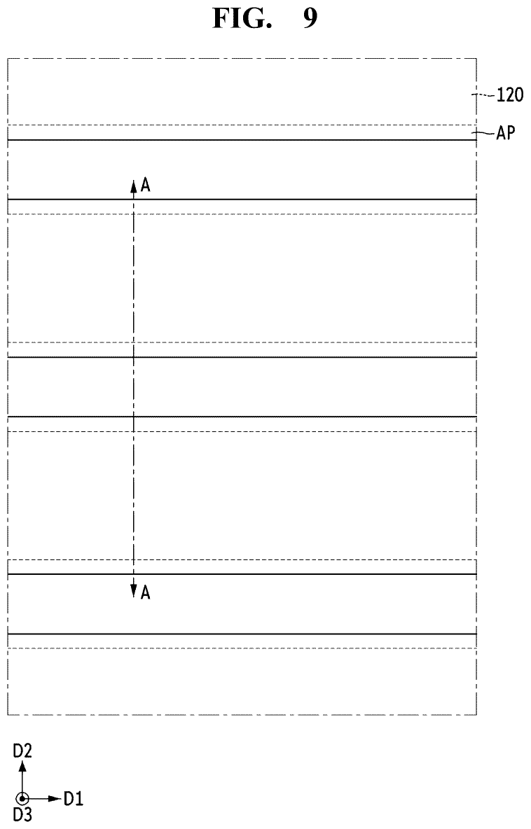

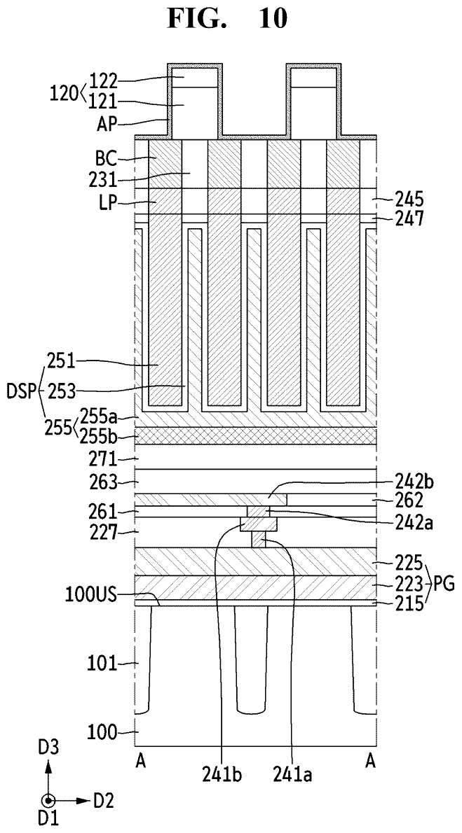

Referring to FIG. 9 and FIG. 10, an active layer AP may be formed on the mold insulating film 120. The active layer AP may conformally cover the mold insulating film 120 and upper surfaces of the buried contact BC and the inter-contact insulating film 231. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied.

For example, the active layer AP may extend along a sidewall and an upper surface of the mold insulating film 120, the upper surface of the buried contact BC, and the upper surface of the inter-contact insulating film 231. The active layer AP may include one of, for example, indium gallium zinc oxide (IGZO), indium zinc oxide (IZO) doped with impurities, indium oxide (InO), zinc oxide (ZnO), gallium oxide (GaO), tin oxide (SnO), aluminum zinc oxide (AZO), and indium tin oxide (ITO). In indium zinc oxide (IZO) doped with the impurities, the doped impurity may include at least one of, for example, magnesium (Mg), strontium (Sr), barium (Ba), scandium (Sc), yttrium (Y), lanthanum (La), titanium (Ti), zirconium (Zr), hafnium (Hf), aluminum (Al), tin (Sn), and tantalum (Ta).

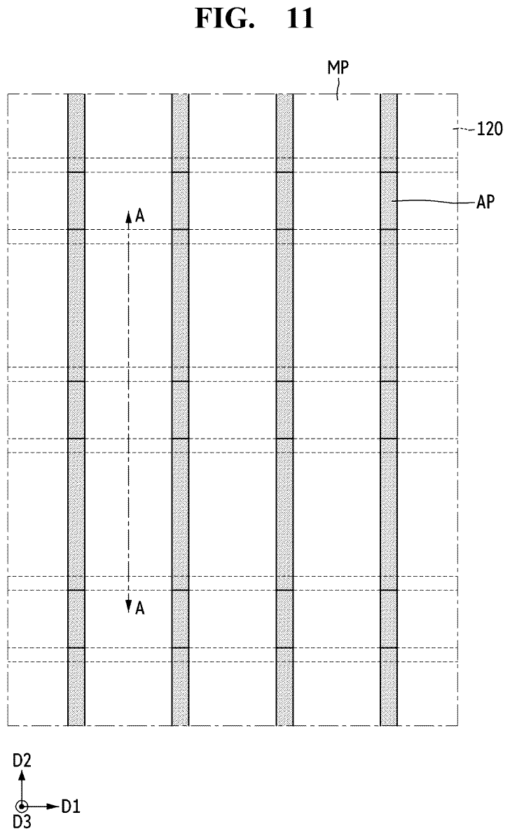

Referring to FIG. 11, a mask pattern MP may be formed on the active layer AP. The mask pattern MP may have openings defined therein, each extending in a line shape along the second direction D2. The openings may be arranged in the first direction D1. Subsequently, the active layer AP may be anisotropically etched using the mask pattern MP as an etch mask.

For reference, a portion of the active layer AP covered with the mask pattern MP is not shown. In other words, the active layer AP is formed on an entirety of an upper surface of the mold insulating film 120 as shown in FIG. 11 while the portion of the active layer AP is covered with the mask pattern MP.

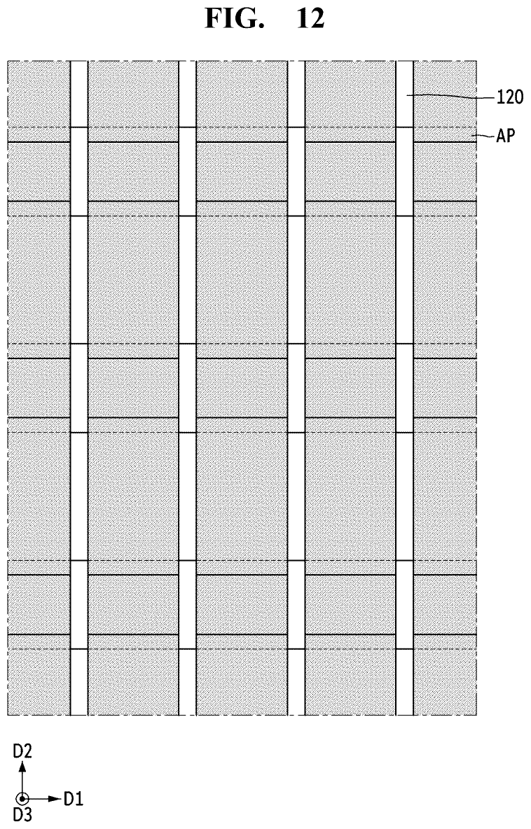

Referring to FIG. 12, a portion of the active layer AP exposed through each of the openings of the mask pattern MP may be removed. The “exposed” (or “exposing,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. The upper surface of the mold insulating film 120 may be exposed in an area from which the portion of the active layer AP has been removed. Subsequently, the mask pattern MP may be removed.

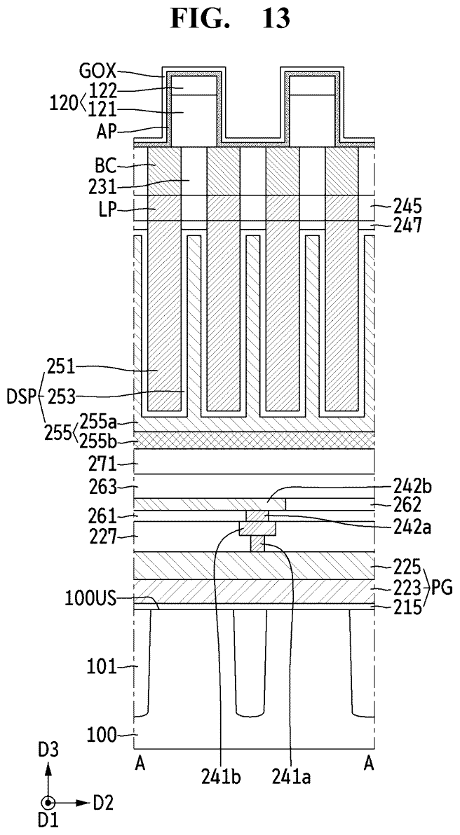

Referring to FIG. 13, the gate insulating pattern GOX may be formed on the active layer AP. The gate insulating pattern GOX may conformally cover the active layer AP.

The gate insulation pattern GOX may be formed using at least one of physical vapor deposition (PVD), thermal CVD, low pressure chemical vapor deposition (LP-CVD), plasma enhanced chemical vapor deposition (PE-CVD), or atomic layer deposition (ALD). However, embodiments of the present disclosure are not limited thereto. For example, the gate insulation pattern GOX may include aluminum oxide (Al₂O₃). However, embodiments of the present disclosure are not limited thereto.

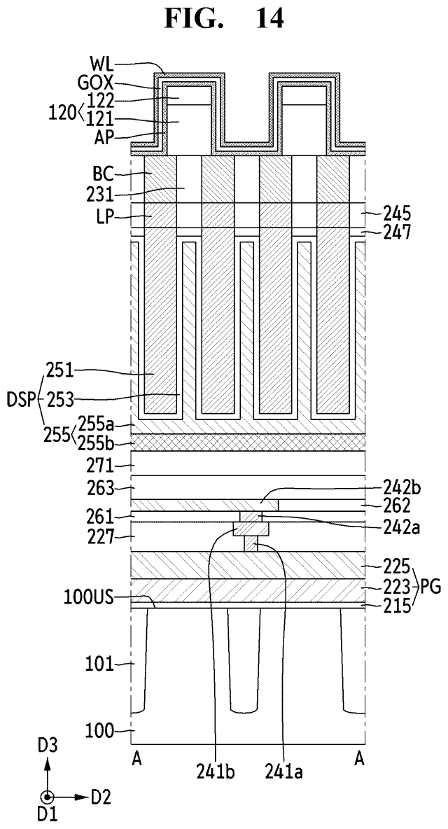

Referring to FIG. 14, a word-line film WL may be formed on the gate insulation pattern GOX. The word-line film WL may conformally cover the gate insulating pattern GOX.

The word-line film WL may be formed using, for example, at least one of physical vapor deposition (PVD), chemical vapor deposition (CVD), and atomic layer deposition (ALD), although embodiments of the present disclosure are not limited thereto. The word-line film WL may include, for example, a conductive material such as metal, metal nitride, or metal silicide, or a semiconductor material such as polysilicon.

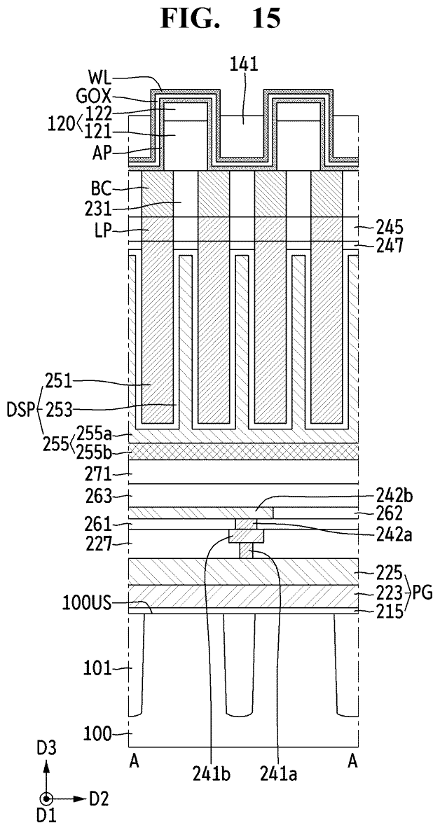

Referring to FIG. 15, a sacrificial film 141 may fill at least a portion of a space between the mold insulating films 120 adjacent to each other in the second direction D2. The term “fill” (or “filling,” or like terms) is intended to refer to either completely filling a defined space (e.g., the space between adjacent mold insulating films 120) or partially filling the defined space; that is, the defined space need not be entirely filled but may, for example, be partially filled or have voids or other spaces throughout.

The sacrificial film 141 may not cover a portion of the word-line film WL formed on the upper surface of the mold insulating film 120.

For example, in forming the sacrificial film 141, a pre-sacrificial film may be formed on the word-line film WL. The pre-sacrificial film may cover a portion of the word-line film WL formed on the upper surface of the mold insulating film 120. The pre-sacrificial film may entirely cover the word-line film WL. Next, a portion of the pre-sacrificial film may be removed to expose the portion of the word-line film WL. As a result, the sacrificial film 141 may be formed.

The sacrificial film 141 may be formed using an organic material, such as, for example, a spin-on hardmask (SOH) material. For example, the sacrificial film 141 may include an inorganic insulating material such as silicon oxide, silicon nitride, and/or silicon oxynitride.

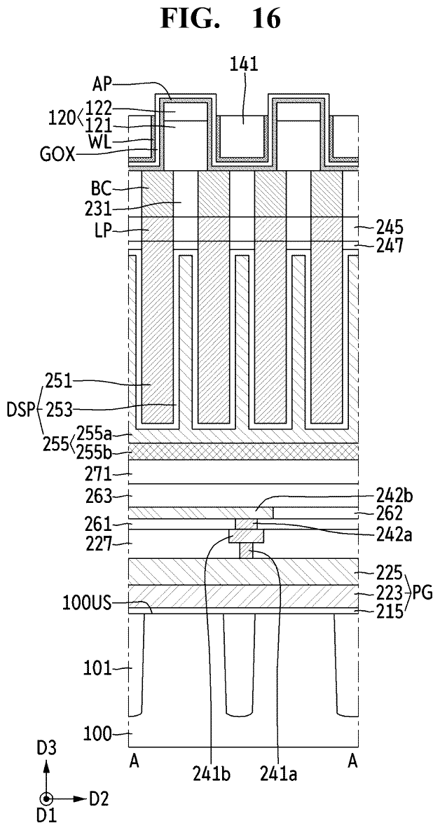

Referring to FIG. 16, a portion of the word-line film WL may be removed by using the sacrificial film 141 as a mask pattern.

For example, the portion of the word-line film WL except for a portion thereof covered with the sacrificial film 141 may be removed.

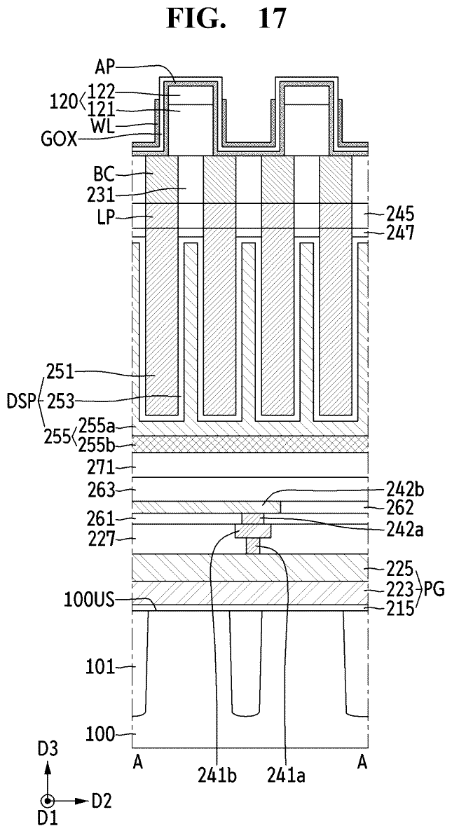

Referring to FIG. 16 and FIG. 17, the sacrificial film 141 may be removed. Specifically, the sacrificial film 141 may be removed through a strip process and/or an ashing process.

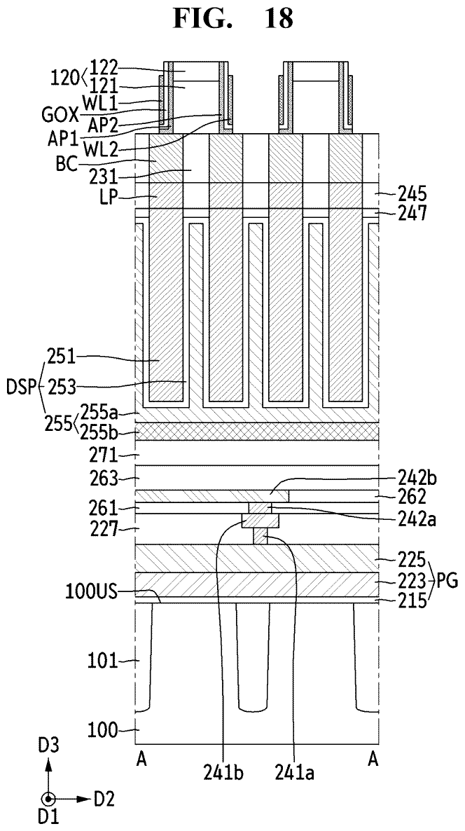

Referring to FIG. 18, a portion of the gate insulation pattern GOX, a portion of the active layer AP, and a portion of the word-line film (see WL in FIG. 17) may be removed.

The removing of the portion of the gate insulating pattern GOX, the portion of the active layer (see AP in FIG. 17), and the portion of the word-line film WL may be performed using a self-aligned etch method.

The portion of the word-line film WL may be removed to form the first word-line WL1 and the second word-line WL2.

The portion of the active layer AP may be removed to form the first active layer AP1 and the second active layer AP2.

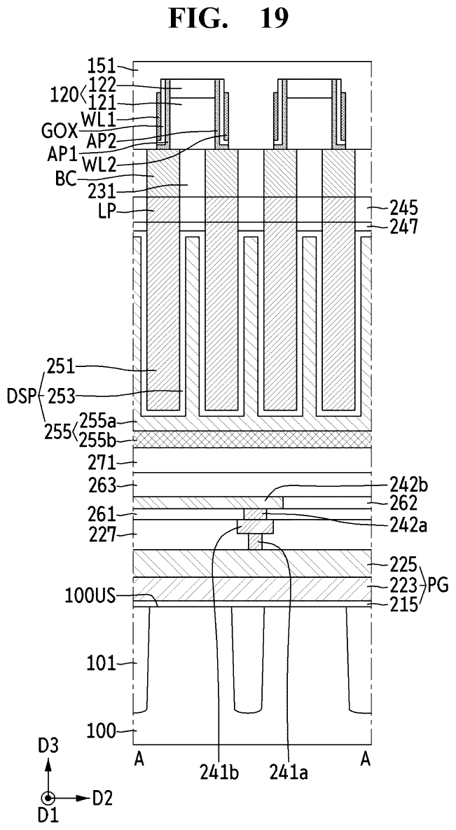

Referring to FIG. 19, the word-line space filling film 151 covering the upper surface of the buried contact BC, the upper surface of the inter-contact insulating film 231, the upper surface of each of the first and second word-lines WL1 and WL2, and the upper surface of the mold insulating film 120 may be formed.

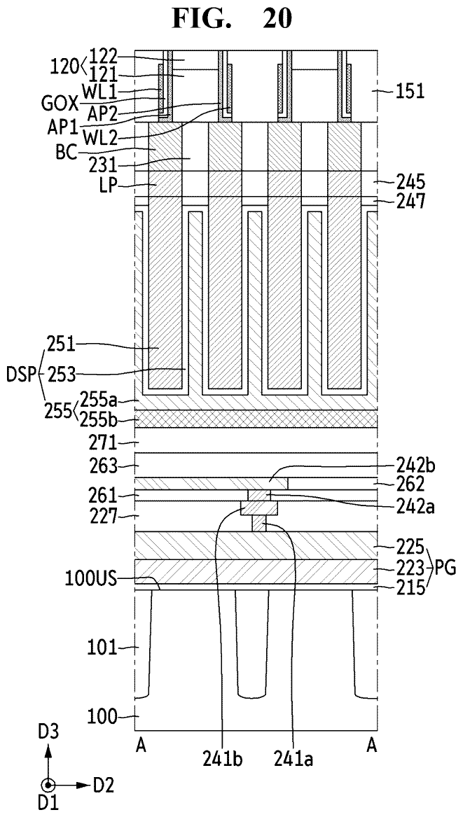

Next, referring to FIG. 20, a portion of the word-line space filling film 151 may be removed. A cross-sectional thickness of the word-line space filling film 151 in the third direction D3 may be reduced compared to a thickness in the third direction D3 of the word-line space filling film 151 shown in FIG. 19. An upper surface of the word-line space filling film 151 may be coplanar with an upper surface of the mold insulating film 120 in the third direction D3.

The portion of the word-line space filling film 151 may be removed using a planarization process. For example, the removing of the portion of the word-line space filling film 151 may be performed using chemical mechanical polishing (CMP).

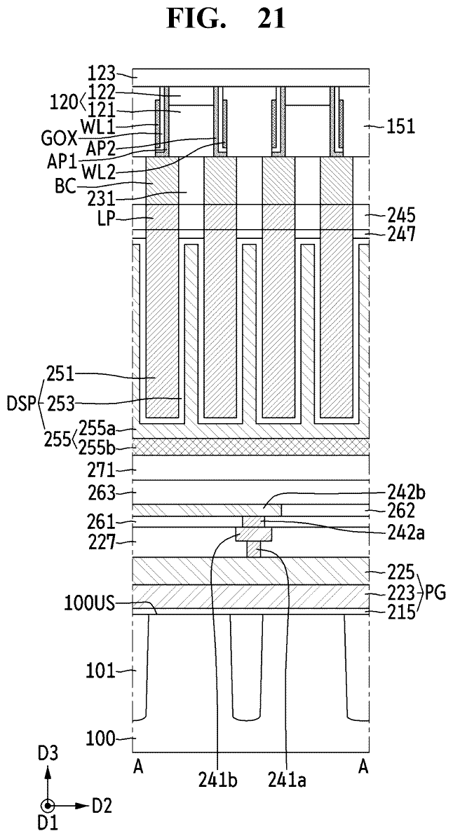

Referring to FIG. 21, the bit-line isolation film 123 may be formed on the word-line space filling film 151 and the mold insulating film 120.

The bit-line isolation film 123 may cover the upper surface of the word-line space filling film 151 and the upper surface of the mold insulating film 120.

For example, the bit-line isolation film 123 may include an insulating material.

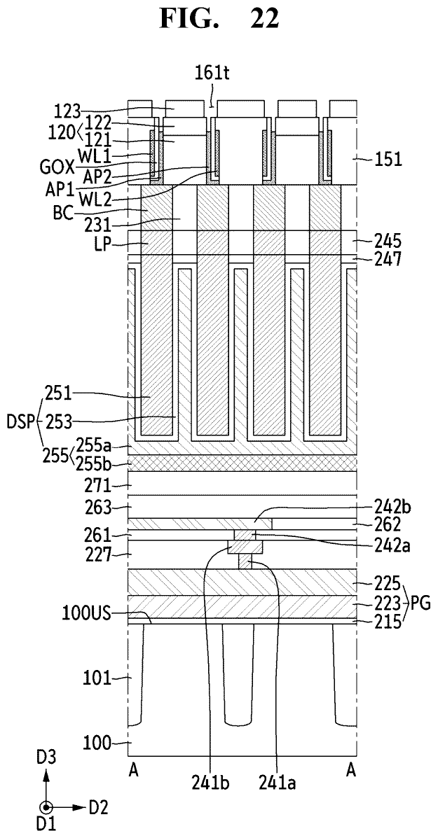

Referring to FIG. 22, a portion of the bit-line isolation film 123 may be removed. Specifically, while the portion of the bit-line isolation film 123 is removed, a portion of each of the first and second channel patterns AP1 and AP2 may be removed. The removing of the portion of the bit-line isolation film 123 and the portion of each of the first and second channel patterns AP1 and AP2 may include a process using etch selectivity.

A portion of the bit-line isolation film 123 may be removed, and the upper surface of each of the first and second channel patterns AP1 and AP2 may be exposed. Specifically, the portion of the bit-line isolation film 123 may be removed, such that a bit-line trench 161t may be formed.

Next, referring to FIG. 4, the bit-line (see BL in FIG. 2) may be formed to fill the bit-line trench (see 161t in FIG. 22). Specifically, the semiconductor pattern 161 of the bit-line BL may be formed to fill the bit-line trench 161t.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor memory device, comprising:
a data storage pattern on a substrate;
a buried contact on the data storage pattern;
a bit-line spaced apart from the buried contact in a first direction and extending in a second direction;
a channel pattern between the buried contact and the bit-line and electrically connected to the buried contact and the bit-line; and
a word-line on the channel pattern and extending in a third direction,
wherein the channel pattern includes a first surface contacting the buried contact and a second surface contacting the bit-line,
wherein a width in the second direction of the first surface of the channel pattern is greater than a width in the second direction of the second surface of the channel pattern.

2. The semiconductor memory device of claim 1, further comprising a gate insulating pattern between the channel pattern and the word-line and extending along a profile of the channel pattern.

3. The semiconductor memory device of claim 2, wherein a distance in the first direction from the buried contact to the second surface of the channel pattern is smaller than a distance in the first direction from the buried contact to an upper surface of the gate insulating pattern.

4. The semiconductor memory device of claim 2, wherein the gate insulating pattern does not directly contact the buried contact.

5. The semiconductor memory device of claim 1, wherein a length in the second direction of the buried contact is different from the length in the second direction of the first surface of the channel pattern.

6. The semiconductor memory device of claim 1, wherein the first surface of the channel pattern is only on the buried contact.

7. The semiconductor memory device of claim 1, wherein at least a portion of the first surface of the channel pattern does not contact the buried contact.

8. The semiconductor memory device of claim 1, wherein the channel pattern includes a first channel pattern and a second channel pattern spaced apart from each other in the second direction,
wherein a mold insulating film is between the first channel pattern and the second channel pattern, and
wherein the first channel pattern and the second channel pattern have a symmetrical structure with respect to each other around the mold insulating film.

9. The semiconductor memory device of claim 8, wherein the mold insulating film includes a first mold insulating film and a second mold insulating film sequentially stacked in the first direction,
wherein at least a portion of the first mold insulating film is in direct contact with the buried contact, and
wherein the second mold insulating film comprises nitrogen.

10. The semiconductor memory device of claim 1, wherein the channel pattern includes a first portion extending in the first direction and a second portion extending in the second direction,
wherein a thickness in the second direction of the first portion of the channel pattern is equal to a thickness in the first direction of the second portion of the channel pattern.

11. The semiconductor memory device of claim 10, wherein the first portion of the channel pattern does not directly contact the buried contact, and
wherein the second portion of the channel pattern is in direct contact with the buried contact and extends along a profile of the buried contact.

12. The semiconductor memory device of claim 1, further comprising a peripheral circuit element on a lower surface of the data storage pattern and electrically connected to the data storage pattern.

13. A semiconductor memory device, comprising:
a data storage pattern on a substrate;
a buried contact on the data storage pattern;
a channel pattern on an upper surface of the buried contact and electrically connected to the buried contact;
a bit-line on the channel pattern, electrically connected to the channel pattern, and extending in a first direction parallel to an upper surface of the substrate; and
a word-line on the channel pattern and between the buried contact and the bit-line, wherein the word-line extends in a second direction parallel to the upper surface of the substrate and intersecting the first direction,
wherein the channel pattern includes a horizontal portion and a vertical portion connected to the horizontal portion,
wherein the horizontal portion of the channel pattern extends in the first direction and along an upper surface of the buried contact, and
wherein the vertical portion of the channel pattern extends from the horizontal portion of the channel pattern in a third direction perpendicular to the upper surface of the substrate.

14. The semiconductor memory device of claim 13, wherein at least a portion of the horizontal portion of the channel pattern does not contact the buried contact.

15. The semiconductor memory device of claim 13, further comprising a gate insulating pattern between the channel pattern and the word-line, and
wherein the gate insulating pattern does not directly contact the buried contact.

16. The semiconductor memory device of claim 13, wherein a thickness in the third direction of the horizontal portion of the channel pattern is equal to a thickness in the first direction of the vertical portion of the channel pattern.

17. A semiconductor memory device, comprising:
a peripheral circuit element on a substrate;
a data storage pattern on the peripheral circuit element;
a buried contact on the data storage pattern;
a bit-line spaced apart from the buried contact in a first direction and extending in a second direction;
a channel pattern between the buried contact and the bit-line and contacting the buried contact and the bit-line; and
a word-line on the channel pattern and extending in a third direction,
wherein the channel pattern includes a first surface contacting the buried contact and a second surface contacting the bit-line, and
wherein a width in the second direction of the first surface of the channel pattern is greater than a width in the second direction of the second surface of the channel pattern.

18. The semiconductor memory device of claim 17, wherein the data storage pattern is between the channel pattern and the peripheral circuit element.

19. The semiconductor memory device of claim 17, wherein the data storage pattern is between the buried contact and the peripheral circuit element.

20. The semiconductor memory device of claim 17, wherein the data storage pattern is between the bit-line and the peripheral circuit element.
